(19) United States
(12) Patent Application Publication
(10) Pub. No.: US 2019/0220073 A1
(43) Pub. Date: Jul. 18, 2019

(54) SERVER DEPLOYMENT METHOD BASED ON DATACENTER POWER MANAGEMENT

(71) Applicant: Huazhong University of Science and Technology, Wuhan (CN)

(72) Inventors: Song WU, Wuhan (CN); Yang Chen, Wuhan (CN); Xinhou Wang, Wuhan (CN); Hai Jin, Wuhan (CN)

(21) Appl. No.: 16/135,404

(22) Filed: Sep. 19, 2018

(30) Foreign Application Priority Data
Jan. 15, 2018 (CN) 201810037874.2

(51) Int. Cl. G06F 1/26; H05K 7/14; G06F 8/60; H04L 29/08; G06F 11/34; G06F 11/30

(52) U.S. Cl. CPC G06F 1/26; H05K 7/1492; G06F 8/60; H04L 67/32; G06F 2201/81; G06F 11/3452; G06F 11/3433; G06F 11/3414; G06F 11/3062; H04L 67/34

(57) ABSTRACT

The present invention relates to a server deployment method based on datacenter power management, wherein the method comprises: constructing a tail latency table and/or a tail latency curve corresponding to application requests based on CPU utilization rate data of at least one server; and determining an optimal power budget of the server and deploying the server based on the tail latency requirement of the application requests. By analyzing the tail latency table or curve, the present invention can, within the limitation of datacenter rated power, on the premise of ensuring the performance of latency-sensitive applications, maximise the deployment density of servers in data centers.

### FIELD

The present invention relates to datacenter management, and more particularly to a server deployment method and system based on datacenter power management.

### BACKGROUND

Oversupply of power is currently a major issue for datacenters. In practice, power reservation for a server is often set according to its rated power or observed peak power, while it is to be ensured that the sum of the power reservation of all the servers in a datacenter is not greater than the total power of that datacenter. However, most servers operate without using its full rated power, and the foregoing reservation renders great waste as to power distribution, confining the server deployment density of a datacenter.

Power capping technology is a way to manage peak power consumption of servers, which involves limiting peak power of a server under a certain level. It is used as a solution to the low resource utilization rate of datacenters as described previously. Obviously, under the confinement imposed by the rated power of a datacenter, the decrease of the power allocation to individual servers means there can be more servers deployed in the datacenter, thereby increasing the calculating capacity of the datacenter, and reducing overhead. However, for latency-sensitive applications, there are usually strict service level agreement (SLA) requirements, and therefore the use of power capping technology with the attempt to improve the resource utilization rate should never undermine SLA requirements of applications. This makes measurement of the impact of power capping on application performance particularly important. Nevertheless, some known approaches to measuring the impact of power capping on application performance are unable to well indicate the actual loss seen in latency-sensitive applications. This is because for latency-sensitive applications what matters is tail latency of requests, yet the existing approaches are mostly designed for batch-processing applications which are more concerned with the final completion time, and fail to precisely measure the impact of power capping on latency-sensitive applications.

For improving the server deployment density of datacenters and in turn the overall resource utilization rate and calculating output, there is a need for a reasonable server deployment scheme. Due to task diversity of datacenters, such a server deployment scheme shall be able to satisfy the following three requirements: 1) the safety of a datacenter must be secured, which means the datacenter should never be overloaded even during its peak time, so as to prevent power failure of the whole datacenter that bring about disastrous crash to all the servers; 2) SLA of applications, namely user experience, shall be ensured; and 3) the resource utilization rate of a datacenter shall be maximized. It is difficult for the existing schemes to meet all three requirements.

### SUMMARY

In view of the shortcomings of the prior art, the present invention provides a server deployment method based on datacenter power management, wherein the method at least comprises: collecting central processing unit (CPU) utilization rate data of at least one server; constructing a tail latency requirement corresponding to application requests based on the CPU utilization rate data of at least one server, the tail latency requirement comprising a tail latency table and/or a tail latency curve, wherein the tail latency table and the tail latency curve of the application requests are constructed under a preset CPU threshold based on the CPU utilization rate data; and determining an optimal power budget of the at least one server based on tail latency requirements of the application requests and deploying the server based on the optimal power budget. By precisely setting power budgets for servers, the present invention not only satisfies the requirements on delayed requests of application, but also maximizes the server deployment density of a datacenter, thereby reducing overhead.

Further, due to adoption of the principle of the overall application task remaining unchanged, the tail latency table and the curve graph of application requests under a fixed CPU threshold can be obtained using calculus. This enables the present invention to the optimal server power budgets according to the requirements on delayed requests set by the user.

According to a preferred aspect, the step of constructing the tail latency table and the tail latency curve corresponding to the application requests comprises: initializing at least one of a request queue, a delayed request table and/or an overall workload w₀, of the application requests based on the preset CPU threshold; setting the CPU utilization rate data Uᵢa collected at an i^{th} moment and its time in the request queue, and updating the overall workload w=w₀+Uᵢ; adjusting an amount of the application requests in the request queue based on comparison between the overall workload w and the CPU threshold; recording data of the delayed requests of the request queue; and when all of the CPU utilization rate data have been iterated, constructing the tail latency table and tail latency curve based on a size order of the data of the delayed requests of the request queue. By iterating the historical sampled CPU data, performance loss can be calculated. With the increase of the frequency of sampling the CPU data, the accuracy of data analysis can be improved accordingly.

According to a preferred aspect, the method further comprises: if the overall workload w is greater than the CPU threshold, deleting the application requests exceeding the CPU threshold from the request queue; and if the overall workload w is not greater than the CPU threshold, deleting all the application requests in the request queue.

By constructing the tail latency table or the tail latency curve, the present invention uses the tail latency as a performance indicator, which when applied to an application relatively sensitive to latency, is more capable to indicate the performance of the application than average latency. The present invention overcomes the difficulty in measuring performance loss of latency-sensitive applications by using calculus to identify latency of every request, thus being very fine-grained.

According to a preferred aspect, the method further comprises: identifying a minimal CPU threshold in the tail latency table and the tail latency curve corresponding to a certain tail latency requirement and using the minimal CPU threshold as the optimal power budget.

According to a preferred aspect, the method further comprises: deploying the at least one server based on the optimal power budget and/or load similarity.

According to a preferred aspect, deployment of the server further comprises: selecting at least one running server similar to the at least one server to be deployed in terms of load and setting the optimal power budget of the at least one server to be deployed identical to that of the running server; comparing a sum of the optimal budget power of the at least one server to be deployed and the optimal budget power of at least one running server in a server rack with a rated power of the server rack; and if the sum is smaller than the rated power, setting the at least one server to be deployed in the rack based on first-fit algorithm.

The present invention determines the power budget optimal to user requirements based on the tail latency table and/or the tail latency curve, and uses the tail latency indicator to reflect the performance of servers, and meets the applications' requirements on delayed requests set by users. The indicator indicates tail latency in the context of large-scale request statistics, and supports good measurement of server performance.

According to a preferred aspect, the method further comprises: for all server racks in a server room, based on first-fit algorithm orderly calculating a sum of the optimal budget power of the at least one server to be deployed and the optimal budget power of all running servers in at least one said server rack. The present invention uses orderly calculation to ensure that servers are deployed in appropriate server racks, instead of random deployment. This maximizes reasonable deployment of servers in a server room. In virtue of first-fit algorithm, servers can be deployed in appropriate server racks in a datacenter.

The present invention provides a server deployment system based on datacenter power management, wherein the system comprises a constructing unit and a deployment unit. The constructing unit constructing a tail latency requirement corresponding to application requests based on CPU utilization rate data of at least one server, the tail latency requirement comprising a tail latency table and a tail latency curve, wherein the constructing unit comprises a collecting module collecting CPU utilization rate data of the at least one server and a latency statistic module constructing the tail latency table and the tail latency curve of the application requests under a preset CPU threshold based on the CPU utilization rate data. The deployment unit determines an optimal power budget of the at least one server based on tail latency requirement of the application requests and deploys the at least one server based on the optimal power budget.

The system improves the performance of datacenters by reducing power consumption while minimizing disruption of performance.

According to a preferred aspect, the latency statistic module at least comprises an initializing module, an adjusting module, and a data-processing module. The initializing module initializes a request queue, a delayed request table and/or an overall workload w₀ of the application requests based on the preset CPU threshold, and sets the CPU utilization rate data Uᵢ collected at an i^{th} moment and its time in the request queue, and updates the overall workload w=w₀+Uᵢ. The adjusting module adjusts an amount of the application requests in the request queue based on comparison between the overall workload w and the CPU threshold, and records data of the delayed requests of the request queue. The data-processing module, when all of the CPU utilization rate data have been iterated, composes the tail latency table and/or tail latency curve based on a size order of the data of the delayed requests of the request queue.

According to a preferred aspect, if the overall workload w is greater than the CPU threshold, the data-processing module deletes the application requests exceeding the CPU threshold from the request queue. Alternatively, if the overall workload w is not greater than the CPU threshold, the data-processing module deletes all the application requests in the request queue.

According to a preferred aspect, the deployment unit comprises a decision-making module. The decision-making module identifies the corresponding minimal CPU threshold from the tail latency table and/or the tail latency curve based on certain tail latency requirement as the optimal power budget.

According to a preferred aspect, the deployment unit further comprises a space-deploying module. The space-deploying module deploys the servers based on the optimal power budgets and/or load similarity.

According to a preferred aspect, the space-deploying module at least comprises a selection module and an evaluation module. The selection module selects at least one running server similar to the server to be deployed in terms of load and setting the optimal power budget of the server to be deployed identical to that of the running server; the evaluation module comparing a sum of the optimal budget power server to be deployed and the optimal budget power of at least one running server in a server rack with a rated power of the server rack; and if the sum is smaller than the rated power, setting the server to be deployed in the rack based on first-fit algorithm.

According to a preferred aspect, the evaluation module orderly calculates a sum of the optimal budget power of the server to be deployed and the optimal budget power of all running servers in at least one said server rack based on first-fit algorithm for all server racks in a server room.

The disclosed server deployment system significantly improves server deployment density and calculating output of a datacenter. In virtue of first-fit algorithm, servers can be deployed in appropriate server racks in a datacenter. Therein, the present invention calculates performance loss by iterating the historical sampled CPU data. With the increase of the frequency of sampling the CPU data, the accuracy of data analysis can be improved accordingly.

The present invention further provides a datacenter power management device, which at least comprises a collecting module, a latency statistic module, a decision-making module and a space-deploying module. The collecting module collects the CPU utilization rate data of the at least one server. The latency statistic module composes the tail latency table and/or the tail latency curve of the application requests under a preset CPU threshold using calculus based on the CPU utilization rate data. The decision-making module identifies the corresponding minimal CPU threshold from the tail latency table and/or the tail latency curve based on certain tail latency requirement as the optimal power budget. The space-deploying module deploys the servers based on the optimal power budgets and/or load similarity.

The disclosed datacenter power management device determines power budgets optimal to servers installed in the rack based on time requirements of delayed requests of applications, and adjusts locations of the servers based on the sum of power of servers in the rack, thereby deploying servers in appropriate server racks in a datacenter.

According to a preferred aspect, the latency statistic module constructing tail latency table and/or tail latency curve by: initializing a request queue, a delayed request table and/or an overall workload w₀, of the application requests based on the preset CPU threshold, setting the CPU utilization rate data Uᵢ collected at an i^{th} moment and its time in the request queue, and updating the overall workload w=w₀+Uᵢ; adjusting an amount of the application requests in the request queue based on comparison between the overall workload w and the CPU threshold, and recording data of the delayed requests of the request queue; and when all of the CPU utilization rate data have been iterated, constructing the tail latency table and/or tail latency curve based on a size order of the data of the delayed requests of the request queue. If the overall workload w is greater than the CPU threshold, the application requests exceeding the CPU threshold are deleted from the request queue. Alternatively, if the overall workload w is not greater than the CPU threshold, all the application requests in the request queue are deleted.

According to a preferred aspect, the space-deploying module deploys servers by: selecting at least one running server similar to the server to be deployed in terms of load and setting the optimal power budget of the server to be deployed identical to that of the running server; comparing a sum of the optimal budget power server to be deployed and the optimal budget power of at least one running server in a server rack with a rated power of the server rack; and if the sum is smaller than the rated power, setting the server to be deployed in the rack based on first-fit algorithm.

According to a preferred aspect, for at least one server rack in a datacenter, the space-deploying module orderly compares a sum of the optimal budget power server to be deployed and the optimal budget power of at least one running server in a server rack with a rated power of the server rack, and determines the spatial location of the server to be deployed based on first-fit algorithm.

The disclosed datacenter power management device uses the tail latency indicator to reflect the performance of servers, and meets applications requirements on delayed request set by users. The indicator indicates tail latency in the context of large-scale request statistics, and supports good measurement of server performance. In addition, the present invention calculates performance loss bt iterating the historical sampled CPU data. With the increase of the frequency of sampling the CPU data, the accuracy of data analysis can be improved accordingly.

### BRIEF DESCRIPTION OF THE DRAWINGS

FIG. 1 is a flowchart of a server deployment method based on datacenter power management according to the present invention;

FIG. 2 is a flowchart of constructing a tail latency table and/or a tail latency curve according to the present invention;

FIG. 3 is a schematic drawing illustrating the operation of constructing the tail latency table and/or the tail latency curve according to the present invention;

FIG. 4 is one tail latency table according to the present invention;

FIG. 5 is one tail latency curve graph according to the present invention;

FIG. 6 shows optimal power budgets of servers according to the present invention;

FIG. 7 is a schematic drawing illustrating deployment of servers according to the present invention;

FIG. 8 is a flowchart of another server deployment according to the present invention;

FIG. 9 is a logic diagram of a server deployment system according to the present invention; and

FIG. 10 is a logic diagram of a power management device for datacenters.

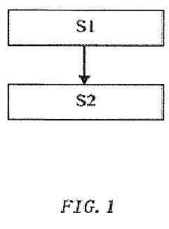

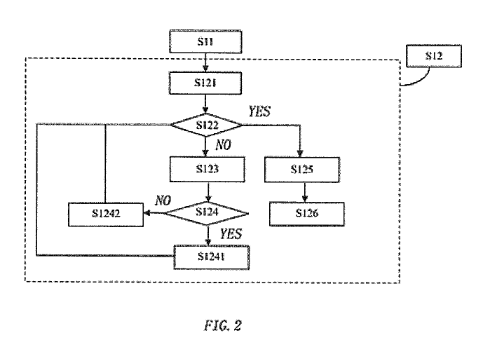

### DETAILED DESCRIPTION OF THE INVENTION

The following description, in conjunction with the accompanying drawings and preferred embodiments, is set forth as below to illustrate the present invention.

It is noted that, for easy understanding, like features bear similar labels in the attached figures as much as possible.

As used throughout this application, the term “may” is of permitted meaning (i.e., possibly) but not compulsory meaning (i.e., essentially). Similarly, the terms “comprising”, “including” and “consisting” mean “comprising but not limited to”.

The phrases “at least one”, “one or more” and “and/or” are for open expression and shall cover both connected and separate operations. For example, each of “at least one of A, B and C”, “at least one of A, B or C”, “one or more of A, B and C”, “A, B or C” and “A, B and/or C” may refer to A solely, B solely, C solely, A and B, A and C, B and C or A, B and C.

The term “a” or “an” article refers to one or more articles. As such, the terms “a” (or “an”), “one or more” and “at least one” are interchangeable herein. It is also to be noted that the term “comprising”, “including” and “having” used herein are interchangeable.

As used herein, the term “automatic” and its variations refer to a process or operation that is done without physical, manual input. However, where the input is received before the process or operation is performed, the process or operation may be automatic, even if the process or operation is performed with physical or non-physical manual input. If such input affects how the process or operation is performed, the manual input is considered physical. Any manual input that enables performance of the process or operation is not considered “physical”.

In the present invention, the term “tail latency” refers to the tail value of processing latency for requests, and is a statistical concept about processing latency for mass requests. Particularly, every request has its processing latency. Most requests can be processed soon, but in a large batch of requests there are always some requests that are processed slowly or have significant latency, so a long tail of processing latency is formed. When the tail is processed too slowly, the requests in this part are perceived as lags, no-response operations and even system crashes that users experience in daily life. This is unacceptable to users. Thus, users pay particular attention to the proportion of such a long tail. For example, some requests are fulfilled in 10 milliseconds, and some requests need 20 milliseconds to be completely processed, while fulfillment of some other requests takes 1 second because of queuing, which is unacceptable to users. When performing statistics on latency of this batch of requests, it may be found, for example, that 95% of the total requests were fulfilled in 50 milliseconds. This means that 95% of the total requests has latency of 50 ms, and 95% may be regarded as the tail proportion that is concerned by users, or the SLA (Service-Level Agreement, a service-level agreement signed by users). In this case, users require that 95% of the total requests have time latency not exceeding 50 milliseconds, and allow 5% of the total requests to be processed relatively slowly. Of course, there may be cases where 99% or another percentage instead of 95% is desired. In the present invention, a tail latency table can be made according to statistic results. The tail latency table carries all the possible percentages, and the corresponding latency values. For example, time latency of 95% of the requests is 50 ms, and time latency of 99% of the requests is 100 ms. All the possible percentages and their latency values are recoded in the table in pairs for checking up.

As a performance indicator, when applied to an application relatively sensitive to time latency, tail latency is more capable to indicate the performance of the application than average latency. To latency-sensitive applications, latency of every request is important and needs to be considered. However, the use of average latency may ignore many details. Assuming that there are two requests, one processed in 10 milliseconds and the other processed in 1 second, so the average latency is 5.5 milliseconds. This disproportionately enlarges latency of the request that is processed much sooner, and undervalues latency of the request that requires more time to process, thus failing to reflect how requests are processed in detail.

### Embodiment 1

The present invention provides a server deployment method based on datacenter power management, which comprises the following steps.

In S1, a tail latency table and/or a tail latency curve corresponding to application requests is constructed based on central processing unit (CPU) utilization rate data of at least one server.

In S2, an optimal power budget of the server is determined and the server is deployed based on tail latency requirement of the application requests. By precisely setting power budgets for servers, the present invention not only satisfies the requirements for delayed requests of application, but also maximizes the server deployment density of a datacenter, thereby reducing overhead.

Preferably, the step of constructing the tail latency table and/or the tail latency curve corresponding to application requests comprises the following steps:
In S11, the CPU utilization rate data of the at least one server are collected.
In S12, the tail latency table and/or the tail latency curve of the application requests under a preset CPU threshold is constructed based on the CPU utilization rate data using calculus. Due to adoption of the principle of the overall application task remaining unchanged, the tail latency table and the curve graph of application requests under a fixed CPU threshold can be obtained using calculus. This enables the present invention to obtain the optimal server power budgets according to the SLA requirements set by the user.

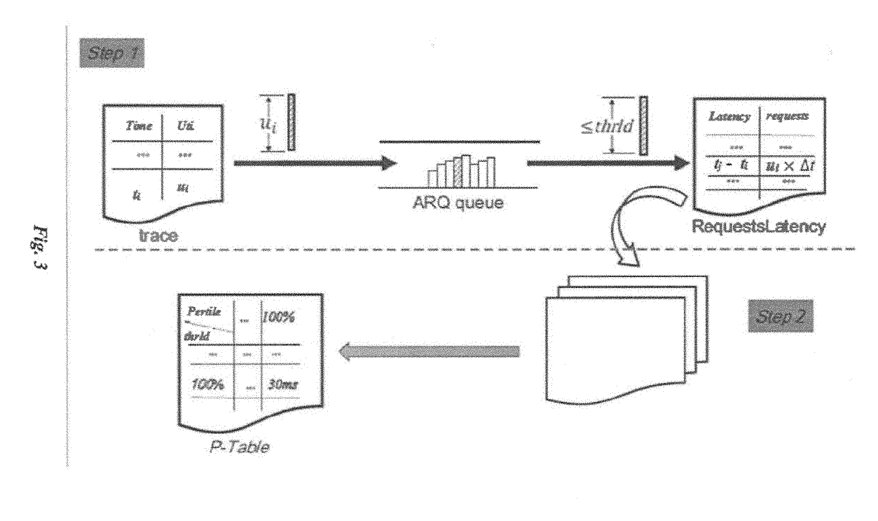

Preferably, the step of constructing the tail latency table and the curve corresponding to the application requests is shown in FIG. 3. The step of constructing the tail latency table and the curve graph corresponding to application requests comprises the following steps.

In S121, a request queue, a delayed request table and/or an overall workload w₀·w₀=0 of the application requests are initialized based on the preset CPU threshold.

In S122, whether all the CPU thresholds have been iterated is determined.

In S123, before the CPU utilization rate data have been completely iterated, the CPU utilization rate data Uᵢ collected at the i^{th} moment and its time are set in the request queue, and the overall workload w=w₀=Uᵢ is updated. Preferably, there is a time interval between the two time points where data are collected. Preferably, the time interval is 5 minutes. In the present invention, the time interval may be countered in minutes, in seconds, in milliseconds, in microseconds, or in nanoseconds, without limitation. As shown in FIG. 3, application requests with various work loads Uᵢ×Δt queue up at the time point tᵢ, forming a request queue of application requests.

In S124, the amount of the application requests in the request queue is adjusted based on comparison between the overall workload w and the CPU threshold, and data of the delayed requests of the request queue are recorded. Therein, calculation of the delayed request data according to the present invention reflects the principle that the overall CPU task load is unchanged. Particularly, whether a CPU threshold is set, the total load of application requests to be processed by the CPU is unchanged. Therefore, the present invention uses the principle of keeping the area integral unchanged to calculate exact latency of a certain differential request.

Preferably, in S1241, when the overall workload w is greater than the CPU threshold, application requests in the request queue exceeding the CPU threshold are deleting, and their latency is recorded in the delayed request table (RequestsLatency). The latency is obtained by subtracting the entering moment from the present moment. As shown in FIG. 3, at the moment the application requests exceeding the maximum work load (thrld×Δt) are deleted. The latency time is tⱼ-31 tᵢ. The latency is recorded in the delayed request table.

In S1242, when the overall workload w is not greater than CPU threshold, all the application requests in the request queue are deleted and their latency is recorded in the delayed request table (RequestsLatency). The latency is obtained by subtracting the entering moment from the present moment.

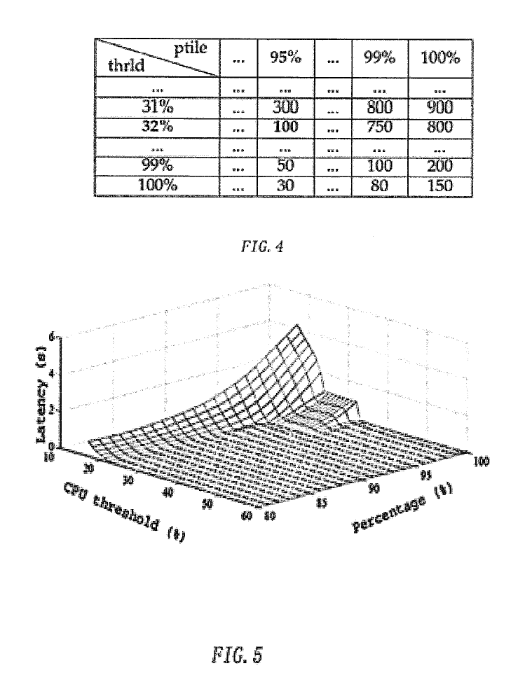

In S125, when all of the CPU utilization rate data have been iterated, the tail latency table and/or tail latency curve is constructed based on a size order of the data of the delayed requests of the request queue. Preferably, it is to be determined whether all the collected data have been iterated. If yes, the delayed requests (RequestsLatency) are sorted by size, so as to obtain the tail latency table or tail latency curve for all the delayed requests. Afterward, the process enters S126 and ends there. As shown in FIG. 3, several formed delayed request tables are sorted by size of latency, so as to form a tail latency table or a tail latency curve. The tail latency table as shown in FIG. 4, and the tail latency curve as shown in FIG. 5. Preferably, the tail latency curve of FIG. 5 is constructed with Webservers under a relatively low CPU utilization rate.

If not, the CPU utilization rate data at the i^{th} moment is collected again. By iterating the historical sampled CPU data, performance loss can be calculated. With the increase of the frequency of sampling the CPU data, the accuracy of data analysis can be improved accordingly.

By constructing the tail latency table or the tail latency curve, the present invention uses the tail latency as a performance indicator, which when applied to an application relatively sensitive to time latency, is more capable to indicate the performance of the application than average latency. The present invention overcomes the difficulty in measuring performance loss of latency-sensitive applications, by using calculus to identify latency of every request, thus being very fine-grained.

Preferably, as shown in FIG. 8, the disclosed method further comprises the following steps.

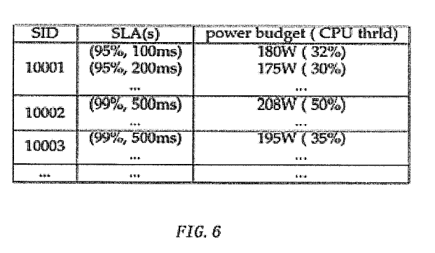

In S21, the corresponding minimal CPU threshold from the tail latency table and/or the tail latency curve is identified based on the certain tail delayed request to act as the optimal power budget. FIG. 6 shows the optimal power budgets of some of the servers.

In S22, the servers are deployed based on the optimal power budgets and/or load similarity.

Preferably, deployment of the server comprises the following steps.

In S221, at least one running server similar to the server to be deployed in terms of load is selected and the optimal power budget of the server to be deployed is set identical to that of the running server.

In S222, it is to determine whether iteration for all the server racks has been done. If yes, the process enters S225 and ends.

In S223, before iteration for all the server racks has not been completed, a sum of the optimal budget power server to be deployed and the optimal budget power of at least one running server in a server rack is compared to a rated power of the server rack.

In S224, if the sum is smaller than the rated power, the server to be deployed in the rack is set based on first-fit algorithm. The present invention determines the power budget optimal to user requirements based on the tail latency table and/or the tail latency curve, and uses the tail latency indicator to reflect the performance of servers, and meets the delayed request requirements of applications set by users. The indicator indicates tail latency in the context of large-scale request statistics, and supports good measurement of server performance.

Preferably, for all server racks in a server room, based on first-fit algorithm orderly calculating a sum of the optimal budget power of the server to be deployed and the optimal budget power of all running servers in at least one said server rack. The present invention uses orderly calculation to ensure that servers are deployed in appropriate server racks, instead of random deployment. This maximizes reasonable deployment of servers in a server room. In virtue of first-fit algorithm, servers can be deployed in appropriate server racks in a datacenter.

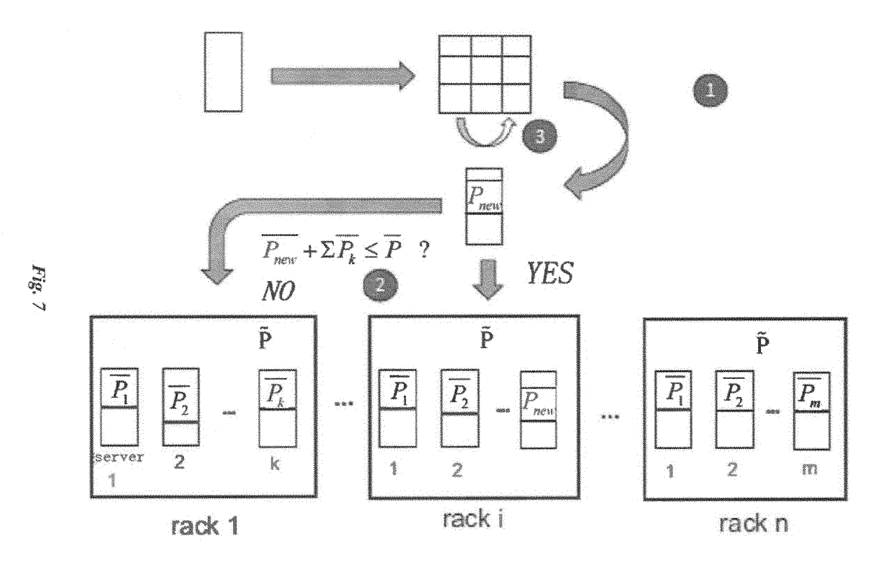

FIG. 7 shows one example of server deployment according to the present invention. Therein, the CPU utilization rate may be 0-100%. The server deployment scheme is described below using an example for which three servers rated 400 W are to be deployed in a rack rated 1000W.

(1) When all the CPU utilization rates are 0, all the servers are in the standby state, where they consume standby power. The standby power is inherent in the servers and is known when the servers left the factory. Assuming that the standby power is 250 W, the total power of the three servers is 250*3=750 W, smaller than the rated power of the server rack, so all of the three server can be deployed in the rack.

(2) When all the CPU utilization rates are 100%, each of the servers is fully loaded at its rated power, namely 400 W. At this time, the total power of the three servers is 400*3=1200 W, greater than the rated power of the server rack, so only two of these servers can be deployed in the rack.

(3) When the CPU utilization rates of the servers are between 0 and 100%, the first thing is to initialize the power budget P̅_̅{̅n̅e̅w̅}̅. According to the historical operational loads of the three servers, namely according to the tail latency table or the tail latency curve, it is determined by calculation that the CPU utilization rate thresholds of the three servers for their optimal power budgets are, for example, 45%, 60%, and 80%, respectively (only exemplary). According to linear mapping between power and the CPU utilization rates, the corresponding power budgets are approximately 317.5 W, 340 W, and 370 W, respectively. At this time, the total power of the three servers is greater than 1000W, and the third server cannot be deployed in the rack. The fundamental for the present invention to deploy servers is that: the threshold of the optimal CPU utilization rate for each server is determined using the method of the present invention. The prerequisite for a server to be deployed in the rack is the sum of the total power is smaller than the rated power of the rack, so as to secure the absolute safety of the rack and prevent power failure or even crush of all the servers due to overload.

### Embodiment 2

The present embodiment is further improvement based on Embodiment 1, and the repeated description is omitted herein.

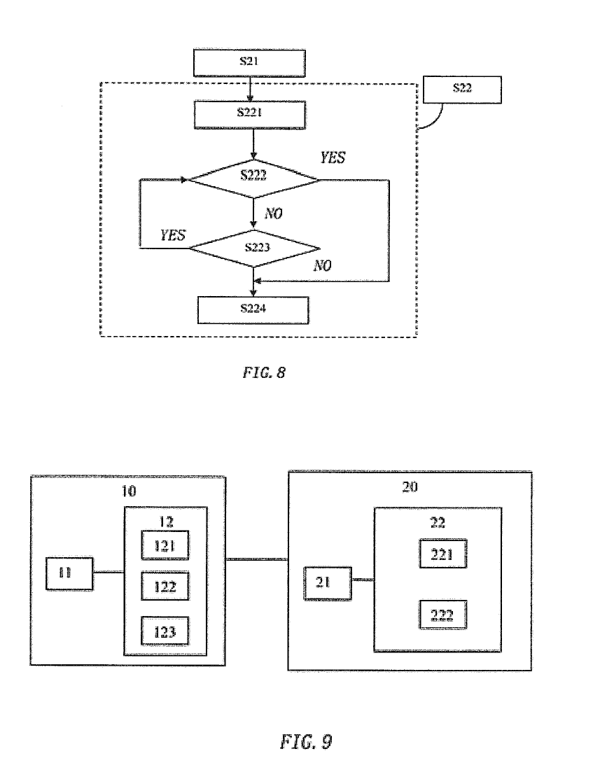

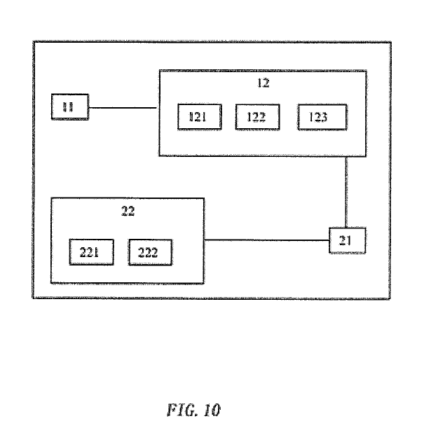

The present invention provides a server deployment system based on datacenter power management, as shown in FIG. 9. The server deployment system based on datacenter power management comprises a constructing unit 10 and a deployment unit 20. The constructing unit 10 composes a tail latency table and/or a tail latency curve corresponding to application requests based on CPU utilization rate data of at least one server. The deployment unit 20 determines an optimal power budget of the server and deploying the server based on tail latency requirement of the application requests. Preferably, the constructing unit 10 comprises one or some of an application-specific IC, a CPU, a microprocessor, a server and a cloud server for collecting the CPU utilization rate and constructing the tail latency table/curve. The deployment unit 20 comprises one or some of an application-specific IC, a CPU, a microprocessor, a server and a cloud server for calculating optimal power budgets.

Preferably, the constructing unit 10 comprises a collecting module 11 and a latency statistic module 12. The collecting module 11 collects CPU utilization rate data of at least one server. The latency statistic module 12 composes the tail latency table and/or the tail latency curve of the application requests under a preset CPU threshold using calculus based on the CPU utilization rate data. Preferably, the collecting module 10 comprises one or some of an application-specific IC, a CPU, a microprocessor, a server and a cloud server for collecting data, transmitting data or selecting data. The latency statistic module 12 comprises one or some of an application-specific IC, a CPU, a microprocessor, a server and a cloud server for calculating latency data and forming the tail latency table and/or the tail latency curve.

Normal servers are equipped with a self-monitoring memory for storing operational data. The present invention uses the collecting module 11 to pick out CPU utilization rate data from the operational data stored in the memory. Preferably, the collecting module 11 may collect real-time CPU utilization rate data of servers in a real-time manner, and may collect the CPU utilization rate data that have been stored in a delay manner.

Preferably, the latency statistic module 12 at least comprises an initializing module 121, an adjusting module 122, and a data-processing module 123. The initializing module 121 initializes a request queue, a delayed request table and/or an overall workload w₀ of the application requests based on the preset CPU threshold, and before the CPU thresholds of all the servers have been completely iterated, sets the CPU utilization rate data Uᵢ collected at the i^{th} moment and its time in the request queue, and updates the overall workload w=w₀+Uᵢ. The adjusting module 122 adjusts an amount of the application requests in the request queue based on comparison between the overall workload w and the CPU threshold, and records delayed request data of the request queue. When all of the CPU utilization rate data have been iterated, the data-processing module 123 composes the tail latency table and/or tail latency curve based on a size order of the data of the delayed requests of the request queue.

Preferably, the initializing module 121 comprises one or some of an application-specific IC, a CPU, a microprocessor, a server and a cloud server for initializing data. The adjusting module 122 comprises one or some of an application-specific IC, a CPU, a microprocessor, a server and a cloud server for adjusting an amount of the application requests in the request queue based on comparison of the overall workload w and the CPU threshold. The data-processing module 123 comprises one or some of an application-specific IC, a CPU, a microprocessor, a server and a cloud server for processing data.

Preferably, if the overall workload w is greater than the CPU threshold, the adjusting module 122 deletes the application requests exceeding the CPU threshold from the request queue, or if the overall workload w is not greater than the CPU threshold, it deletes all the application requests in the request queue.

Preferably, the deployment unit 20 comprises a decision-making module 21. The decision-making module 21 identifies the corresponding minimal CPU threshold from the tail latency table and/or the tail latency curve based on certain tail latency requirement as the optimal power budget. The decision-making module 21 comprises one or some of an application-specific IC, a CPU, a microprocessor, a server and a cloud server for setting and selecting the optimal power budget.

The deployment unit 20 further comprises a space-deploying module 22. The space-deploying module 22 deploys the servers based on optimal power budget and/or load similarity. The space-deploying module 22 comprises one or some of an application-specific IC, a CPU, a microprocessor, a server and a cloud server for calculating and allocating spatial locations of servers.

Preferably, the space-deploying module 22 at least comprises a selection module 221 and an evaluation module 222. The selection module 221 selects at least one running server similar to the server to be deployed in terms of load and sets the optimal power budget of the server to be deployed to be the same as that of the running server. The evaluation module 222 compares a sum of the optimal budget power server to be deployed and the optimal budget power of at least one running server in a server rack with a rated power of the server rack. If the sum of the budget power is smaller than the rated power, the evaluation module 222 sets the server to be deployed in the rack based on first-fit algorithm.

Preferably, for all server racks in a server room, the evaluation module 222 orderly calculating a sum of the optimal budget power of the server to be deployed and the optimal budget power of all running servers in at least one said server rack based on the first-fit algorithm.

Preferably, the selection module 221 comprises one or some of an application-specific IC, a CPU, a microprocessor, a server and a cloud server for selecting servers based on load similarity or optimal budget power. The evaluation module 222 comprises one or some of an application-specific IC, a CPU, a microprocessor, a server and a cloud server for calculating locations for servers to be deployed.

The disclosed server deployment system significantly improves server deployment density and calculating output of a datacenter. In virtue of first-fit algorithm, servers can be deployed in appropriate server racks in a datacenter. Therein, the present invention calculates performance loss by iterating the historical sampled CPU data. With the increase of the frequency of sampling the CPU data, the accuracy of data analysis can be improved accordingly.

### Embodiment 3

The present embodiment is further improvement based on Embodiment 1 or 2, and the repeated description is omitted herein.

The present invention further provides a datacenter power management device, as shown in FIG. 10. The datacenter power management device at least comprises a collecting module 11, a latency statistic module 12, a decision-making module 21, and a space-deploying module 22. The collecting module collects CPU utilization rate data of at least one server. The latency statistic module 12 composes the tail latency table and/or the tail latency curve of the application requests under a preset CPU threshold using calculus based on the CPU utilization rate data. The decision-making module 21 identifies the corresponding minimal CPU threshold from the tail latency table and/or the tail latency curve based on certain tail latency requirement as the optimal power budget. The space-deploying module 22 deploys the servers based on the optimal power budgets and/or load similarity.

The disclosed datacenter power management device determines power budgets optimal to servers installed in the rack based on time requirements of delayed requests of applications, and adjusts locations of the servers based on the sum of power of servers in the rack, thereby deploying servers in appropriate server racks in a datacenter.

Preferably, the latency statistic module 12 composes the tail latency table and/or the tail latency curve by: initializing a request queue, a delayed request table and/or an overall workload w₀ of the application requests based on the preset CPU threshold; setting the CPU utilization rate data Uᵢ collected at the i^{th} moment and its time in the request queue and updating the overall workload w=w₀+Uᵢ; adjusting an amount of the application requests in the request queue based on comparison between the overall workload w and the CPU threshold, and recording the delayed request data of the request queue; and when all of the CPU utilization rate data have been iterated, constructing the tail latency table and/or tail latency curve based on a size order of the data of the delayed requests of the request queue. Therein, if the overall workload w is greater than the CPU threshold, the application requests in the request queue exceeding the CPU threshold are deleted. If the overall workload w is not greater than the CPU threshold, all the application requests in the request queue are deleted.

Preferably, the space-deploying module 22 deploys servers by: selecting at least one running server similar to the server to be deployed in terms of load and setting the optimal power budget of the server to be deployed identical to that of the running server; comparing a sum of the optimal budget power server to be deployed and the optimal budget power of at least one running server in a server rack with a rated power of the server rack; and if the sum is smaller than the rated power, setting the server to be deployed in the rack based on first-fit algorithm.

Preferably, for at least one server rack of the datacenter, the space-deploying module 22 orderly compares a sum of the optimal budget power server to be deployed and the optimal budget power of at least one running server in a server rack with a rated power of the server rack; and determines the spatial location of the server to be deployed based on first-fit algorithm.

The disclosed datacenter power management device uses the tail latency indicator to reflect the performance of servers, and meets the applications' requirements on delayed requests set by users. The indicator indicates tail latency in the context of large-scale request statistics, and supports good measurement of server performance. In addition, the present invention calculates performance loss by iterating historical sampled CPU data. With the increase of the frequency of sampling the CPU data, the accuracy of data analysis can be improved accordingly.

The disclosed datacenter power management device overcomes the difficulty in measuring performance loss of latency-sensitive applications. The present invention uses calculus to identify latency of every request, thus being very fine-grained, and thereby providing users with reasonable suggestions about the power thresholds according the service-level agreement entered by users, helping users to deploy servers in their datacenters. Therefore, the present invention can not only promise the performance of applications, but also significantly improve the resource utilization rate.

Preferably, the disclosed datacenter power management device is one or some of an application-specific IC, a CPU, a microprocessor, a server, a cloud server and a cloud platform for datacenter power management. Preferably, the datacenter power management device further comprises storage module. The storage module comprises one or more of a memory, a server, and a cloud server for storing data. The storage module is connected to the collecting module 11, the latency statistic module 12, the decision-making module 21 and the space-deploying module 22, respectively, in a wired or wireless manner, thereby transmitting and storing the data of each of these modules. Preferably, the collecting module 11, the latency statistic module 12, the decision-making module 21 and the space-deploying module 22 perform data transmission with the storage module through buses.

Preferably, the collecting module 11 selects the CPU utilization rate data based on the various monitored operational data in the running server, and performs extraction and selection thereon. The latency statistic module 12 calculates and processes the CPU utilization rate data delivered by the collecting module 11, so as to form the tail latency curve or the tail latency table.

In the present embodiment, the collecting module 11, the latency statistic module 12, the decision-making module 21 and the space-deploying module 22 are structurally identical to the collecting module, the latency statistic module, the decision-making module and the space-deploying module as described in Embodiment 2.

What is claimed is:

1. A server deployment method based on datacenter power management, wherein the method comprises:
collecting central processing unit (CPU) utilization rate data of at least one server;
constructing a tail latency requirement corresponding to application requests based on the CPU utilization rate data of the at least one server, the tail latency requirment comprising a tail latency table and a tail latency curve, wherein the tail latency table and the tail latency curve of the application requests are constructed under a preset CPU threshold based on the CPU utilization rate data;
determining an optimal power budget of the at least one server based on the tail latency requirement of the application requests; and
deploying the at least one server based on the optimal power budget.

2. The server deployment method of claim 1, wherein the step of constructing the tail latency table and tail latency curve corresponding to the application requests further comprises:
initializing at least one of a request queue, a delayed request table and/or an overall workload w₀ of the application requests based on the preset CPU threshold;
setting the CPU utilization rate data Uᵢ collected at an i^{th} moment and its time in the request queue, and updating the overall workload according to w=w₀+Uᵢ;
adjusting the amount of the application requests in the request queue based on comparison between the overall workload w and the CPU threshold, and recording data of the delayed requests of the request queue; and
when all of the CPU utilization rate data have been iterated, constructing the tail latency table and tail latency curve based on a size order of the data of the delayed requests of the request queue.

3. The server deployment method of claim 2, further comprising:
if the overall workload w is greater than the CPU threshold, deleting the application requests exceeding the CPU threshold from the request queue; and
if the overall workload w is not greater than the CPU threshold, deleting all the application requests in the request queue.

4. The server deployment method of claim 3, further comprising:
identifying a minimal CPU threshold in the tail latency table and the tail latency curve corresponding to a certain tail latency requirement and using the minimal CPU threshold as the optimal power budget.

5. The server deployment method of claim 1, further comprising:
deploying the at least one server based on the load similarity.

6. The server deployment method of claim 1, wherein the server deployment method further comprises:
selecting at least one running server similar to the at least one server to be deployed in terms of load and setting the optimal power budget of the at least one server to be deployed identical to that of the running server;
comparing the sum of the optimal budget power of the at least one server to be deployed and the optimal budget power of at least one running server in a server rack with the rated power of the server rack; and
if the sum is smaller than the rated power, setting the at least one server to be deployed in the rack based on first-fit algorithm.

7. The server deployment method of claim 6, further comprising:
for all server racks in a server room, orderly calculating a sum of the optimal budget power of the at least one server to be deployed and the optimal budget power of all running servers in at least one said server rack based on the first-fit algorithm.

8. A server deployment system based on datacenter power management, wherein the system comprises a constructing unit and a deployment unit,
the constructing unit constructing a tail latency requirement corresponding to application requests based on central processing unit (CPU) utilization rate data of at least one server, the tail latency requirement comprising a tail latency table and a tail latency curve, wherein the constructing unit comprises a collecting module collecting CPU utilization rate data of the at least one server and a latency statistic module constructing the tail latency table and the tail latency curve of the application requests under a preset CPU threshold based on the CPU utilization rate data; and
the deployment unit determining an optimal power budget of the at least one server based on the tail latency requirement of the application requests and deploying the at least one server based on the optimal power budget.
